(19) United States
(12) Patent Application Publication
(10) Pub. No.: US 2009/0111283 A1
(43) Pub. Date: Apr. 30, 2009

(54) METHOD FOR FORMING INTERLAYER INSULATING FILM OF SEMICONDUCTOR DEVICE

(75) Inventors: Myoung Soo Kim, Gangnam-gu (KR); Kew Chan Shim, Hwaseong-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-Si (KR)

(21) Appl. No.: 12/041,402

(22) Filed: Mar. 3, 2008

(30) Foreign Application Priority Data
Oct. 31, 2007 (KR) 10-2007-0110678

(51) Int. Cl. H01L 21/469

(52) U.S. Cl. 438/780; 257/E21.259

(57) ABSTRACT

A method for forming an interlayer insulating film of a semiconductor device comprises forming an active pattern over a substrate, forming a spin-on dielectric film over the substrate including the active pattern, and irradiating an electron beam over the spin on dielectric film to form an interlayer insulating film.

### CROSS-REFERENCE TO RELATED APPLICATION

The priority of Korean patent application number 10-2007-0110678, filed on Oct. 31, 2007, the disclosure of which is incorporated by reference in its entirety, is claimed

### BACKGROUND OF THE INVENTION

1. Field of the Disclosure

The invention relates to a method for forming an interlayer insulating film of a semiconductor device.

2. Brief Description of Related Technology

Due to rapid distribution of information media such as computers, semiconductor device technology has advanced rapidly. Semiconductor devices should simultaneously be operated at a high speed and have a high storage capacity. Therefore, process equipment and technology development have been required to manufacture a semiconductor device having improved integration, reliability, and an electronic characteristic of accessing data with low manufacturing cost.

As semiconductor devices have been reduced in size, the line size of a highly-integrated circuit of a semiconductor device and gaps between the lines have also become smaller. As a result, it is difficult to uniformly fill a fine gap between the lines using a general method when the interlayer insulating film is formed. For example, a general method may comprise depositing a spin on glass (SOG) material by a chemical vapor deposition (CVD) method, or by a plasma enhanced CVD (PE-CVD) method.

In order to uniformly fill the fine gap between the lines, more precise methods for forming an interlayer insulating film are required. Of these methods, a method for forming a high density plasma (HDP) oxide film by a CVD method has been developed. The method using an HDP oxide film is performed by a deposition process and an in-situ etching process simultaneously in order to increase ionization efficiency as compared to a PE-CVD method. That is, the method includes applying an electric field and a magnetic field, and simultaneously providing a source gas, a source power, an etching gas, and a bias power to deposit an HDP oxide film as an interlayer insulating film. The source power is to decompose the source gas and then to generate plasma from the source gas. The process for deposition the insulating film is performed by chemical reaction of the decomposed source gases. The bias power is for etching the deposited insulating film. Here, the etching process is performed by ionization of inactive etching gases.

When the gap between the lines is smaller than 80nm, the gap-fill capacity of HDP oxide film degrades. As a result, a void 12 is generated in the interlayer insulating film 11 which is formed by the HDP oxide film (see FIG. 1, which shows a structure manufactured by a conventional method wherein the insulating film 11 is the HDP oxide film, the pattern 10 is a active pattern such as line/space pattern, contact hole pattern, and a metal line pattern, and the void 12 is formed in the insulating film 11). When the interlayer insulating film 11 is coated in order to fill the pattern 10, an overhang phenomenon occurs where an oxide material is deposited in an entrance of the gap more rapidly than an inner side of the gap. As a result, a void is generated in the inner side of the gap.

As the width of the gap becomes smaller and the gap deeper, the gap-fill capacity of the material for forming an interlayer insulating film is degraded to generate a void. In the operation of the device, the void causes a leakage current, thereby degrading reliability of the device.

In order to minimize generation of voids, a spin on dielectric (SOD) film, which is deposited at low temperature with an excellent gap-fill capacity has been widely used.

Referring to FIG. 2, the SOD material 20 is coated to fill a gap between fine patterns 21. An oxidation process is performed at a temperature ranging from 300° C. to 600° C. in the presence of a platinum catalyst. The wafer is annealed at a temperature ranging from 300° C. to 600° C. for 30 minutes to four hours. However, this condition does not improve the effect to fill the gap between fine patterns, thereby generating a void 22.

### SUMMARY OF THE INVENTION

Various embodiments of the invention are directed at providing a method for forming an interlayer insulating film which comprises irradiating an electron beam instead of a high temperature annealing process after coating a spin-on-dielectric (SOD) film so as to fill a gap between fine patterns without voids.

According to an embodiment of the invention, a method for forming an interlayer insulating film of a semiconductor device comprises preparing a substrate including an active pattern. An SOD film is formed over the substrate including the active pattern. An electron beam is irradiated over the SOD film to form an interlayer insulating film.

The active pattern includes a line and space (L/S) pattern, a hole pattern having a large step difference, and a metal line pattern. Specifically, the L/S pattern comprises a pattern for forming an isolating region/active region, a gate pattern, and a bit-line pattern. The hole pattern comprises a storage node contact and a metal contact. The metal line pattern is preferably formed of tungsten, tungsten silicide, cobalt, cobalt silicide, titanium silicide, or aluminum.

The SOD film is preferably formed of silicon, carbon, hydrogen, nitrogen, and oxygen as a low-k organic material having a dielectric constant lower than that of quartz (about 4). The SOD film preferably comprises a material having silicon-nitrogen (Si—N) bond structure and a degree of dispersion ranging from 8.0 to 1.1. Specifically, the SOD film preferably comprises an organic solvent and a compound selected from the group consisting of silazane compounds, slises-quioxane compounds, and combinations thereof. The silazane compound preferably comprises a perhydro-polysilazane [(SH₂NH)n] (n is a natural number) or a polysilazane. The slises-quioxane compound preferably comprises a methyl slises-quioxane or a hydrogen slises-quioxane. The compounds preferably have a molecular weight ranging from 500 to 10000.

The organic solvent preferably comprises at least member selected from the group consisting of dibutylether, ethyl 3-ethoxy propionate, methyl 3-methoxy propionate, cyclohexanone, propylenegylcol methyl ether acetate, methyl ethylketone, benzene, toluene, dioxane, dimethyl formamide, and mixtures thereof. The organic solvent is preferably present in an amount ranging from 150 parts by weight to 500 parts by weight based on 100 parts by weight of the compound.

The electron beam is preferably irradiated with an accelerated voltage ranging from 1 KeV to 50 KeV for 5 seconds to 40 seconds per wafer under an atmosphere gas pressure ranging from 10 mmtorr to 50 mmTorr and an accelerated voltage ranging from 1 KeV to 50 KeV per a wafer in a reaction chamber. The wafer preferably has a diameter in the range of 60 nm to 800 nm. The electron beam region is preferably irradiated by a light source has a size determined by a size of a control grid. The size preferably ranges from 0.10 μm to 12 μm. In the electron beam irradiation process, a reaction chamber is preferably set at 10° C. to 400° C. under a pressure preferably ranging from 5 Torr to 40 Torr and an atmosphere gas flow rate preferably ranging from 2 sccm to 20 sccm. The atmosphere gas is preferably selected from the group consisting of nitrogen gas, oxygen gas, argon gas, and helium gas. Specifically, the electron beam is preferably irradiated under an oxygen atmosphere. The electron beam is preferably irradiated with multiple irradiation and multiple voltages by a proximity method or contact method. The electron beam irradiation process can be repeatedly performed, if desired.

### BRIEF DESCRIPTION OF THE DRAWINGS

FIG. 1 is a diagram and a pattern photograph illustrating a void generated in a conventional process for forming an interlayer insulating film.

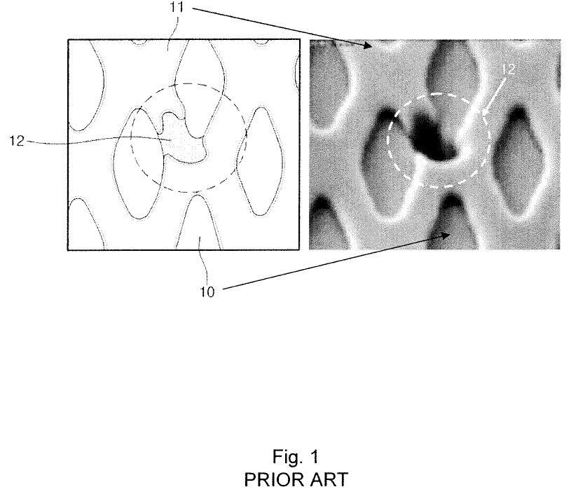

FIG. 2 is a diagram and a pattern photograph illustrating a void generated in a conventional process for forming an interlayer insulating using an annealing process.

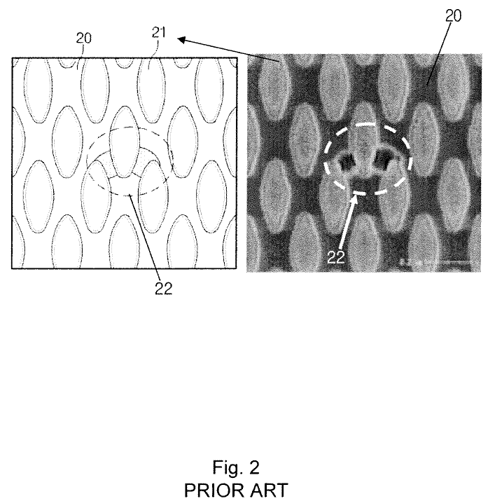

FIG. 3 is a diagram illustrating an improved white voltage contrast (VC) by an electron beam process.

FIG. 4 is a graph illustrating a Weibull distribution.

FIG. 5 is a diagram and a pattern photograph of Comparative Example 1.

FIG. 6 is a diagram and a pattern photograph of Example 1.

FIG. 7 is a diagram and a pattern photograph of Example 2.

FIG. 8 is a diagram and a pattern photograph of Example 3.

FIG. 9 is a diagram and a pattern photograph of Example 4.

FIG. 10 is a diagram and a pattern photograph of Example 5.

FIG. 11 is a diagram and a pattern photograph of Example 6.

FIG. 12 is a graph illustrating a subsequent etching process resulting from an electron beam irradiating process of Experimental Example 1.

### DETAILED DESCRIPTION OF SPECIFIC EMBODIMENTS

The invention provides a method for forming an interlayer insulating film of a semiconductor device comprising: forming a spin-on-dielectric (SOD) film over a substrate including an active pattern; and irradiating an electron beam over the SOD film to form an interlayer insulating film. The following description provides exemplary descriptions of embodiments of the invention, but the invention is not limited to the illustrated embodiments.

The SOD film preferably comprises a material having Si—N bonds such as perhydro-polysilazane. An electron beam is preferably irradiated on the SOD film under an oxygen atmosphere. A part of electron beams reacts with an oxygen atmosphere before reaching the wafer to generate oxygen radicals. Other electron beams supply active energy to the SOD film formed over the wafer to cleave a part of the Si—N bond, thereby generating silicon radicals. As shown in Formula 1, the silicon radicals react with the oxygen radicals to obtain silicon oxide (SiO₂). The silicon oxide is filled the gap uniformly between the active patterns without voids.

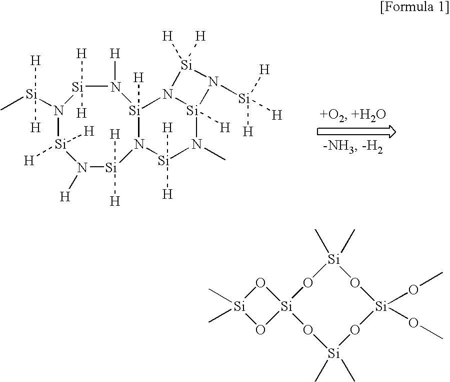

The oxidation reaction for substituting the silicon-nitrogen bond with a silicon-oxygen bond is performed while an electron beam is irradiated under an oxygen atmosphere instead of under an atmosphere with high temperature and high pressure. Therefore, the method for depositing an interlayer insulating film can be simplified and deposition time can be shortened.

After the interlayer insulating film is formed, a planarization process and an etch-back process are performed. Depending on hardness of the interlayer insulating film, the interlayer insulating film is removed with an irregular etching speed. In order to obtain the uniform hardness of the interlayer insulating film, it is necessary to minimize remaining Si—N bond structure in the interlayer insulating film. In a conventional method, an annealing process is performed to remove the Si—N bond structure. However, an ammonia (NH3) gas is generated in the annealing process to cause generation of voids.

In an embodiment of the invention, the oxidation process using the electron beam is irradiated to minimize the remaining of the Si—N bond structure, thereby obtaining an interlayer insulating film having a uniform hardness. As a result, an additional thermal process is not performed to remove the Si—N bond structure, thereby improving generation of voids.

In an embodiment of the invention, an interlayer insulating film having a uniform thickness can be obtained without voids.

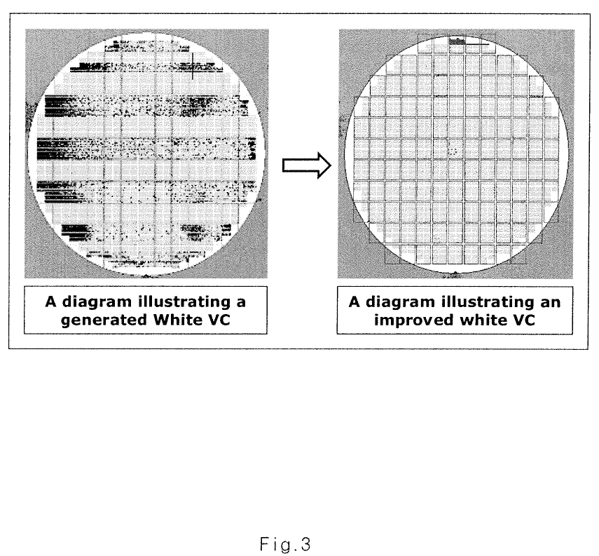

As described above, according to the disclosed embodiment of the invention, when a field oxide film is formed with a SOD film, generation of voids is prevented to improve a current leakage effect and a white voltage contrast (VC) in comparison with the interlayer insulating film which is not applied with an electron beam irradiation process (see FIG. 3).

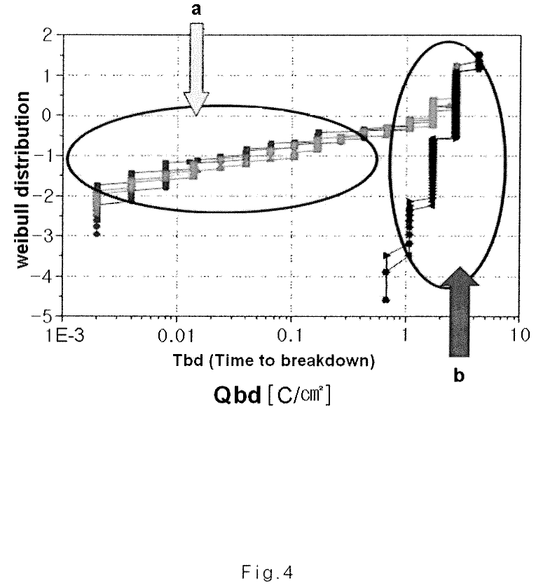

More specifically, a review of a Weibull distribution shows that gate oxide integrity (GOI) and charge to breakdown (Qbd) are improved, thereby reducing a leakage current of the device. That is, a constant current is given to the same sized wafers comprising the interlayer insulating film which have a void or do not have a void, and a time to breakdown (Tbd, axis x) is measured to draw a cumulative plot. In the interlayer insulating film having a void, a Tbd is generated right after a current is transmitted. However, in the interlayer insulating film having no void, a Tbd is not generated up to a considerable time after a current is transmitted. Generally, a Qbd is Tbd * (stress current). If a current of −0.1 A/cm² is transmitted, Qbd=0.1* Tbd (C/cm²). When the current strength is differentiated, a Qbd value is also differentiated. In case of common devices for performing a stable operation, the Qbd is satisfied to be more than ±1 C/cm². When many voids are generated in the interlayer insulating film, (a) the Tbd is generated right after a current is transmitted as shown in FIG. 4. As a result, a Qbd value is so low that a leakage current is increased. However, when no voids are generated in the interlayer insulating film, (b) the Tbd is not generated up to a considerable time after a current is transmitted. As a result, a Qbd value is so high that a leakage current is prevented.

The method will be described in detail by referring to examples below, which are not intended to be limiting.

### COMPARATIVE EXAMPLE 1

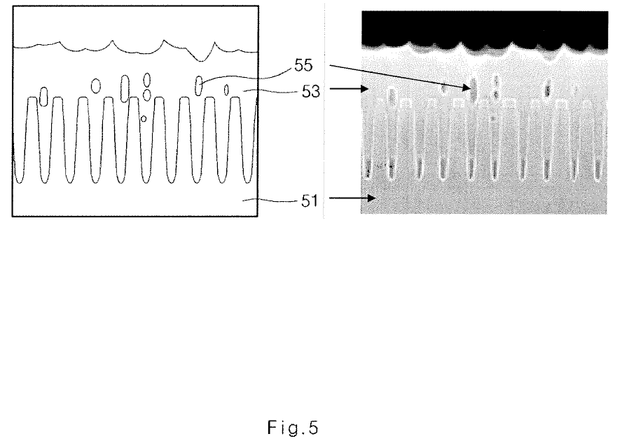

Referring to FIG. 5, 20 wt % perhydro-polysilazane (produced by AZ-EM Co.) was coated over a wafer having 800 nm diameter 51 including an active pattern. The resulting structure was baked to remove a solvent on the wafer at 120° C. for 5 minutes, and oxidized with a platinum catalyst under a high temperature (at 300° C.) and a high pressure. The resulting structure was annealed at 500° C. for 2 hours to form a interlayer insulating film 53 which is filled in a gap between the active patterns. When a cross-section of an interlayer insulating film was measured by an electron microscope, a void 55 was generated in the interlayer insulating film.

### EXAMPLE 1

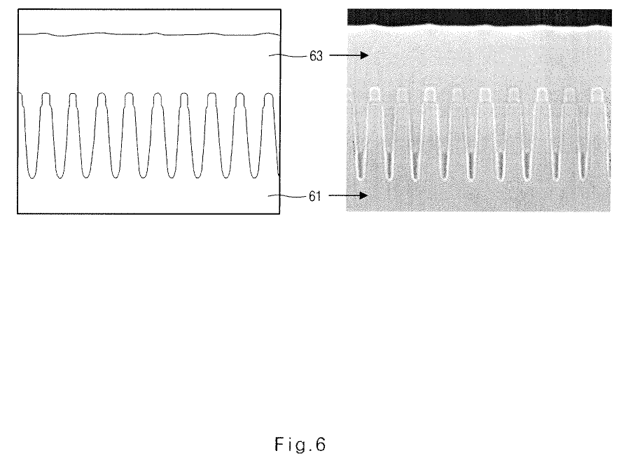

Referring to FIG. 6, 19 wt % perhydro-polysilazane (produced by AZ-EM Co.) dissolved in di-n-butylether was coated over a wafer having 800 nm diameter 61 including an active metal pattern. The resulting structure was baked to remove a solvent at 120° C. for 5 minutes. A three-step electron beam is irradiated with a voltage of 40 KeV for 15 seconds into a reaction chamber, thereby forming an interlayer insulating film 63. The reaction chamber was set to have an oxygen atmosphere at 23° C. under a pressure of 10 Torr a flowing rate an oxygen gas of 5 sccm therein. When a cross-section of an interlayer insulating film was measured by an electron microscope, an interlayer insulating film was uniformly filled in a gap between fine patterns without voids.

### EXAMPLE 2

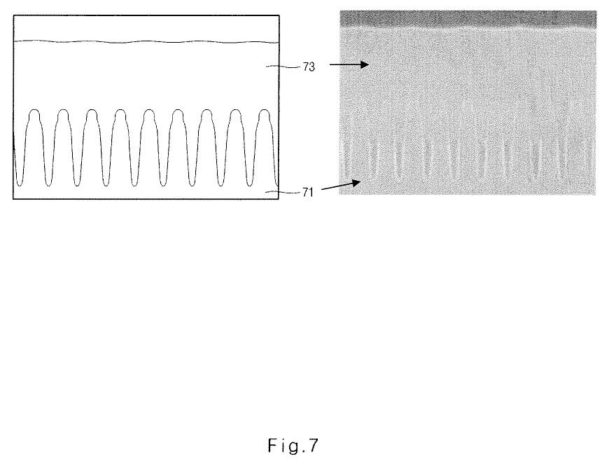

Referring to FIG. 7, 23 wt % perhydro-polysilazane (produced by AZ-EM Co.) dissolved in di-n-butylether was coated over a wafer having 800 nm diameter 71 including an active metal pattern. The resulting structure was baked to remove a solvent at 130° C. for 5 minutes. A two-step electron beam was irradiated with a voltage of 50 KeV for 10 seconds into a reaction chamber, thereby forming an interlayer insulating film 73. The reaction chamber was set to have an oxygen atmosphere at 23° C. under a pressure of 20 Torr and a flowing rate of 7 sccm of an oxygen gas therein. When a cross-section of an interlayer insulating film was measured by an electron microscope, an interlayer insulating film was uniformly filled in a gap between fine patterns without voids.

### EXAMPLE 3

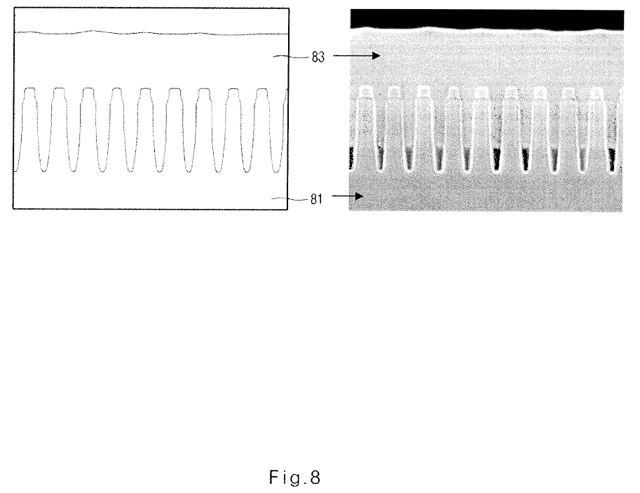

Referring to FIG. 8, 25 wt % perhydro-polysilazane (produced by AZ-EM Co.) dissolved in di-n-butylether was coated over a wafer having 800 nm diameter 81 including an active metal pattern. The resulting structure was baked to remove a solvent at 130° C. for 5 minutes. A three-step electron beam was irradiated with a voltage of 30 KeV for 20 seconds into a reaction chamber, thereby forming an interlayer insulating film 83. The reaction chamber was set to have an oxygen atmosphere at 23° C. under a pressure of 30 Torr and a flowing rate of 8 sccm of an oxygen gas therein. When a cross-section of an interlayer insulating film was measured by an electron microscope, an interlayer insulating film was uniformly filled in a gap between fine patterns without voids.

### EXAMPLE 4

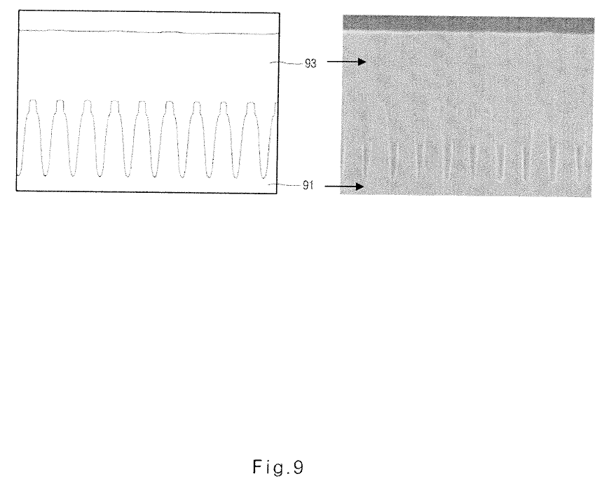

Referring to FIG. 9, 17 wt % perhydro-polysilazane (produced by AZ-EM Co.) dissolved in di-n-butylether was coated over a wafer having 800 nm diameter 91 including an active metal pattern. The resulting structure was baked to remove a solvent at 110° C. for 5 minutes. A three-step electron beam was irradiated with a voltage of 40 KeV for 15 seconds into a reaction chamber, thereby forming an interlayer insulating film 93. The reaction chamber was set to have an oxygen atmosphere at 23° C. under a pressure of 15 Torr and a flowing rate of 5 sccm of an oxygen gas therein. When a cross-section of an interlayer insulating film was measured by an electron microscope, an interlayer insulating film was uniformly filled in a gap between fine patterns without voids.

### EXAMPLE 5

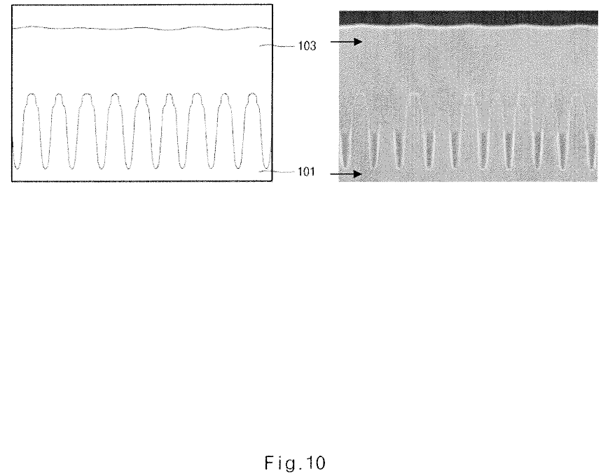

Referring to FIG. 10, 19 wt % perhydro-polysilazane (produced by AZ-EM Co.) dissolved in di-n-butylether was coated over a wafer having 800 nm diameter 101 including an active metal pattern. The resulting structure was baked to remove a solvent at 120° C. for 5 minutes. A three-step electron beam was irradiated with a voltage of 40 KeV for 15 seconds into a reaction chamber, thereby forming an interlayer insulating film 103. The reaction chamber was set to have an oxygen atmosphere at 23° C. under a pressure of 10 Torr a flowing rate of 5 sccm of an oxygen gas therein. When a cross-section of an interlayer insulating film was measured by an electron microscope, an interlayer insulating film was uniformly filled in a gap between fine patterns without voids.

### EXAMPLE 6

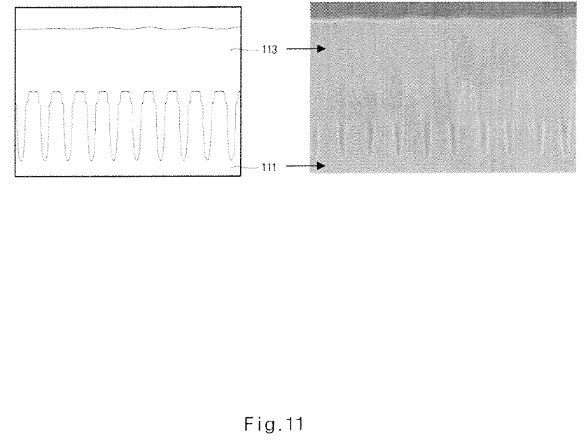

Referring to FIG. 11, 24 wt % perhydro-polysilazane (produced by AZ-EM Co.) dissolved in di-n-butylether was coated over a wafer having 800 nm diameter 111 including an active metal pattern. The resulting structure was baked to remove a solvent at 120° C. for 5 minutes. A three-step electron beam was irradiated with a voltage of 30 KeV for 12 seconds into a reaction chamber, thereby forming an interlayer insulating film 113. The reaction chamber was set to have an oxygen atmosphere at 23° C. under a pressure of 10 Torr a flowing rate of 10 sccm of an oxygen gas therein. When a cross-section of an interlayer insulating film was measured by an electron microscope, an interlayer insulating film was uniformly filled in a gap between fine patterns without voids.

### EXAMPLE 7

24 wt % perhydro-polysilazane (produced by AZ-EM Co.) dissolved in di-n-butylether was coated over a wafer having 800nm diameter including an active metal pattern. The resulting structure was baked to remove a solvent at 120° C. for 5 minutes. A three-step electron beam was irradiated with a voltage of 30 KeV for 12 seconds into a reaction chamber, thereby forming an interlayer insulating film. The reaction chamber was set to have an oxygen atmosphere at 23° C. under a pressure of 10 Torr a flowing rate of 10 sccm of an oxygen gas therein. When a cross-section of an interlayer insulating film was measured by an electron microscope, an interlayer insulating film was uniformly filled in a gap between fine patterns without voids.

### EXPERIMENTAL EXAMPLE 1

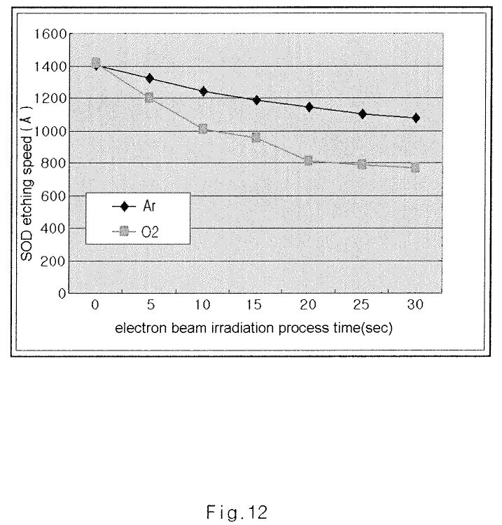

The same procedure (oxygen gas) of Example 6 was repeatedly performed for 0˜30 seconds to obtain an interlayer insulating film. Also, the same procedure (argon gas) of Example 7 was repeatedly performed for 0˜30 seconds to obtain an interlayer insulating film. A wet etching process was performed on the interlayer insulating films. As a result, the etching speed of the interlayer insulating film formed by using an oxygen gas was slower than that using an argon gas (see FIG. 12).

In the electron beam irradiation process using an oxygen gas, oxygen radicals are generated more than in the electron beam irradiation process using an argon gas. As a result, the oxygen radicals react with silicon radicals to minimize remaining the Si—N bond structure in the interlayer insulating film, thereby obtaining a uniform hardness of the interlayer insulating film. The interlayer insulating film in the electron beam irradiation process using an oxygen gas is etched with a slower speed than in that using an argon gas.

As described above, according to an embodiment of the invention, an electron beam is irradiated after a SOD film is coated, thereby simplifying a process for forming an interlayer insulating film and preventing generation of voids in the interlayer insulating film.

The above embodiments of the present invention are illustrative and not limitating. Various alternatives and equivalents are possible. The invention is not limited by the lithography steps described herein, nor is the invention limited to any specific type of semiconductor device. For example, the present invention may be implemented in a dynamic random access memory (DRAM) device or non volatile memory device. Other additions, subtractions, or modifications are obvious in are intended to fall within the scope of the appended claims.

What is claimed is:

1. A method for forming an interlayer insulating film of a semiconductor device, the method comprising:
providing a substrate including an active pattern;
forming a spin-on-dielectric film over the substrate including the active pattern; and
irradiating an electron beam over the spin-on-dielectric film to form an interlayer insulating film.

2. The method according to claim 1, wherein the active pattern is a line and space (L/S) pattern, a hole pattern, or a metal line pattern.

3. The method according to claim 1, wherein the spin-on-dielectric film comprises a composition containing an organic solvent and a compound selected from the group consisting of silazane compounds, slises-quioxane compounds, and combinations thereof.

4. The method according to claim 3, wherein the compound has a molecular weight ranging from 500 to 10,000.

5. The method according to claim 3, wherein the silazane compound comprises perhydro-polysilazane.

6. The method according to claim 3, wherein the silazane compound comprises a polysilazane.

7. The method according to claim 3, wherein the slises-quioxane compound comprises a methyl slises-quioxane or a hydrogen slises-quioxane.

8. The method according to claim 3, wherein the organic solvent is selected from the group consisting of dibutylether, ethyl 3-ethoxy propionate, methyl 3-methoxy propionate, cyclohexanone, propylenegylcol methyl ether acetate, methyl ethylketone, benzene, toluene, dioxane, dimethyl formamide, and mixtures thereof.

9. The method according to claim 3, wherein the organic solvent is present in an amount ranging from 150 parts by weight to 500 parts by weight based on 100 parts by weight of the compound.

10. The method according to claim 1, comprising irradiating the electron beam in a reaction chamber with an accelerated voltage ranging from 1 KeV to 50 KeV for 5 seconds to 40 seconds under an atmosphere gas pressure ranging of 10 mmTorr to 50 mmTorr per a wafer.

11. The method according to claim 10, wherein the wafer has a diameter ranging from 60 nm to 800 nm.

12. The method according to claim 10, comprising irradiating the electron beam in the reaction chamber at a temperature of 10° C. to 400° C. and an atmosphere gas flow rate of 2 sccm to 20 sccm.

13. The method according to claim 12, wherein the atmosphere gas is selected from the group consisting of nitrogen gas, oxygen gas, argon gas, and helium gas.

14. The method according to claim 1, comprising irradiating an electron beam by a proximity method or contact method.

15. The method according to claim 1, comprising repeatedly irradiating the electron beam.
